(19) United States
(12) Patent Application Publication
(10) Pub. No.: US 2025/0046574 A1
(43) Pub. Date: Feb. 6, 2025

(54) CONTINUOUS PROCESSING MECHANISM FOR DUAL EFFECT PLASMA ETCHING

(71) Applicant: UVAT TECHNOLOGY CO.,LTD., Taoyuan City (TW)

(72) Inventors: YUAN-CHI LEE, Taoyuan City (TW); PIN-CHUN LIU, Taoyuan City (TW); MING-CHAN TSAI, Taoyuan City (TW)

(21) Appl. No.: 18/382,071

(22) Filed: Oct. 20, 2023

(30) Foreign Application Priority Data
Aug. 2, 2023 (TW) 112129056

(51) Int. Cl. H01J 37/32

(52) U.S. Cl. CPC H01J 37/32174; H01J 37/32449; H01J 37/32743; H01J 37/32816; H01J 37/32899; H01J 2237/334

(57) ABSTRACT

A continuous processing mechanism for dual effect plasma etching used for performing a plasma etching process on a substrate includes a high-speed etching vacuum chamber and a low-speed etching vacuum chamber. The high-speed etching vacuum chamber includes a first radio frequency plasma module to carry out a high-speed plasma etching on the substrate. The low-speed etching vacuum chamber includes a first buffer area, a linear plasma area, and a second buffer area that are in communication with each other. The linear plasma area has a first linear plasma module. The substrate moves between the first buffer area, the linear plasma area, and the second buffer area, allowing the first linear plasma module to carry out a low-speed plasma etching thereon. Therefore, the present invention fulfills the requirements of the etching efficiency of the continuous processing mechanism and the fineness of the substrate surface.

### BACKGROUND OF THE INVENTION

### 1. Field of the Invention

The present invention relates to continuous processing mechanisms, and more particularly, to a continuous processing mechanism for dual effect plasma etching.

### 2. Description of the Related Art

Plasma technology uses a specific gas in a vacuum environment in cooperation with an external energy generated by the electrode to enable the electrons in the gas to gain energy, such that the gas molecules are ionized to generate plasma, which is applied to the surface cleaning, etching, or coating operation of an object. The conventional plasma process equipment used in etching operation has high etching efficiency, but, due to its low precision, it is mainly used for cleaning or etching of printed circuit boards, or large-scale etching processes in semiconductor processes. For semiconductor and wafer processes requiring a nanometer scale precision, it is still needed to use traditional etching and development process machines, whose cost of processing equipment is relatively higher. Also, regarding the application of plasma in the etching process for developer removal, it is still needed to take the maintenance of an optimal vacuum level, production efficiency, and etching accuracy into consideration, so as to improve the issues of poor evenness of a large area etching operation of semiconductors, thereby achieving a high etching efficiency and improving the processing yield simultaneously.

Therefore, it is desirable for the industry to solve the issues above.

### SUMMARY OF THE INVENTION

The present invention aims at improving the issues of a low etching precision of a conventional plasma etching machine which is not suitable for application in semiconductor manufacturing processes.

The aforementioned objectives do not prevent the existence of other objectives. Those objectives derivable from the specification, claims, or drawings of the present invention by a person having ordinary skill in the field of the invention are also included in the scope of objectives of the present invention. Therefore, the objectives of the present invention are not limited to the aforementioned objectives.

For achieving the aforementioned objectives, the present invention provides a continuous processing mechanism for dual effect plasma etching for carrying out the plasma etching process on at least a substrate. The continuous processing mechanism comprises a high-speed etching vacuum chamber and a low-speed etching vacuum chamber. The high-speed etching vacuum chamber comprises a first radio frequency plasma module configured to carry out a high-speed plasma etching process on the substrate. The low-speed etching vacuum chamber is connected with the high-speed etching vacuum chamber, and comprises a first buffer area, a linear plasma area, and a second buffer area that are orderly connected and in communication with each other. The first buffer area neighbors the high-speed etching vacuum chamber. The linear plasma area comprises a first linear plasma module therein for carrying out a low-speed plasma etching process on the substrate. The substrate is allowed to unidirectionally move or reciprocate between the first buffer area, the linear plasma area, and the second buffer area, so as to carry out the low-speed plasma etching process thereon.

With such configuration, the present invention achieves following technical features.

The present invention carries out the high-speed etching process on the substrate through the first radio frequency plasma module in the high-speed etching vacuum chamber, so as to efficiently obtain the substrate underwent a deep level etching operation, and then carries out the even and fine etching process on the substrate through the first linear plasma module in the low-speed etching vacuum chamber, so as to obtain the substrate underwent a fine etching operation. Therefore, the present invention simultaneously meets the high etching efficiency and substrate surface fineness requirement of the continuous processing mechanism.

The first linear plasma module is a direct current linear electrode, which is capable of providing an even and fine etching effect to the substrate, thereby preventing the issue of uneven roughness of the substrate surface.

In the present invention, the substrate is allowed to reciprocate between the first buffer area, the linear plasma area, and the second buffer area, so as to completely pass through the first linear plasma module for achieving an even etching effect of the substrate surface.

### BRIEF DESCRIPTION OF THE DRAWINGS

FIG. 1 is a perspective view of the continuous processing mechanism in accordance with a preferred embodiment of the present invention.

FIG. 2 is a front sectional view of the high-speed etching vacuum chamber in accordance with a preferred embodiment of the present invention.

FIG. 3 is a schematic view of the circuit of the first radio frequency plasma module in accordance with a preferred embodiment of the present invention.

FIG. 4 is a schematic view of the circuit of the first radio frequency plasma module in accordance with another preferred embodiment of the present invention.

FIG. 5 is a schematic view of the low-speed etching vacuum chamber in accordance with a preferred embodiment of the present invention.

FIG. 6 is a top view of the continuous processing mechanism in accordance with another preferred embodiment of the present invention.

### DETAILED DESCRIPTION OF THE INVENTION

The aforementioned and further advantages and features of the present invention will be understood by reference to the description of the preferred embodiment in conjunction with the accompanying drawings where the components are illustrated based on a proportion for explanation but not subject to the actual component proportion.

Embodiments of the present invention are illustrated in detail along with the drawings. However, the technical features included by the present invention are not limited to certain embodiments hereby provided. Scope of the present invention shall be referred to the claims, which include all the possible replacements, modifications, and equivalent features.

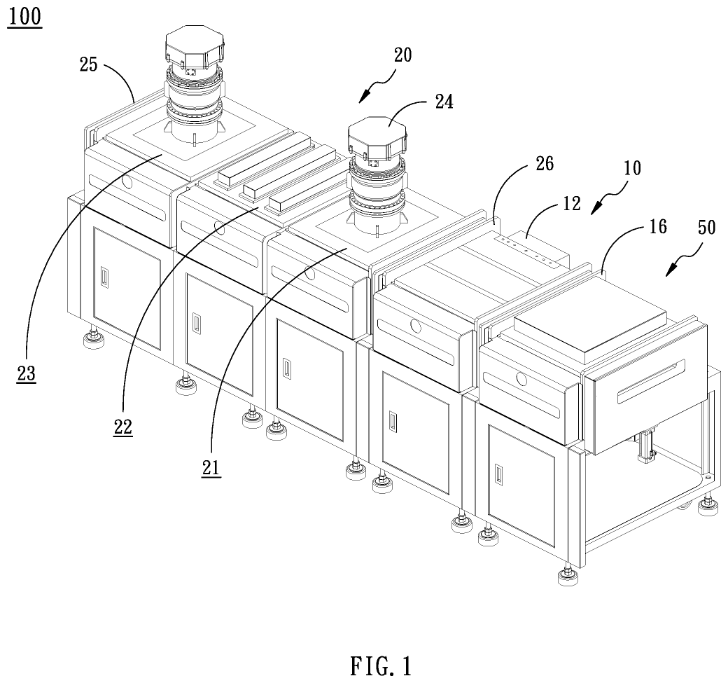

Referring to FIG. 1 to FIG. 6, in an embodiment of the present invention, a continuous processing mechanism 100 of dual effect plasma etching is provided for carrying out a plasma etching process on at least one substrate 1. The continuous processing mechanism 100 comprises a high-speed etching vacuum chamber 10 and a low-speed etching vacuum chamber 20. The substrate 1 is allowed to be an electronic or semiconductor object that requires etching, such as, for example but not limited to, a wafer, chip, composite carrier, or ABF carrier.

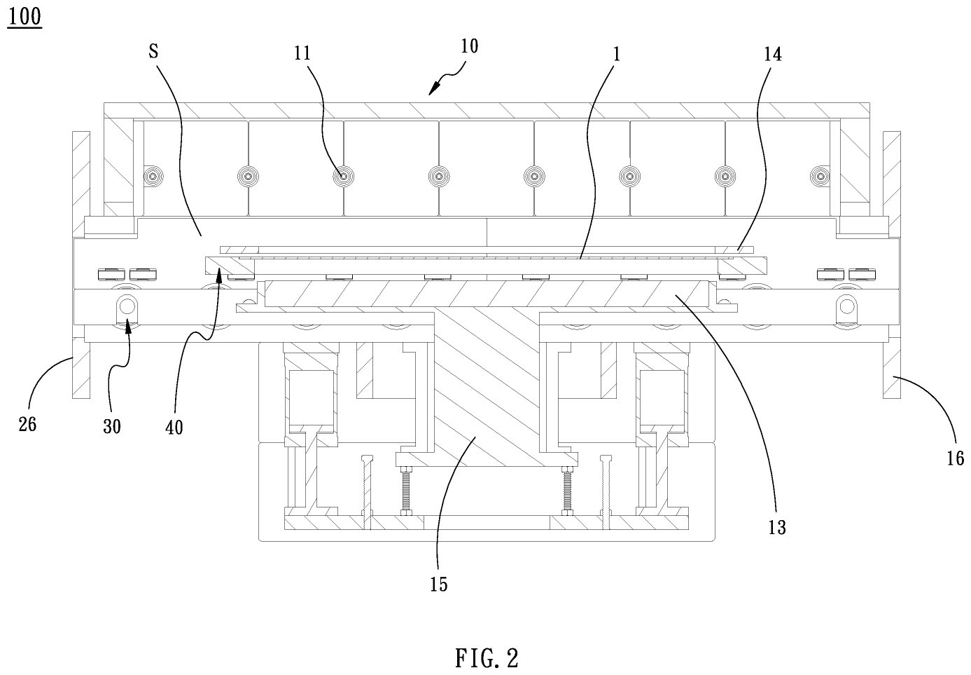

The present invention comprises a conveyance device 30 disposed between the high-speed etching vacuum chamber 10 and the low-speed etching vacuum chamber 20 for conveying the substrate 1, as shown by FIG. 2. In other words, the conveyance device 30 conveys the substrate 1 to the high-speed etching vacuum chamber 10 for etching. In another embodiment, the continuous processing mechanism 100 comprises a carrier board 40 for holding the substrate 1 to be conveyed by the conveyance device 30.

The high-speed etching vacuum chamber 10 comprises a first radio frequency plasma module 11, which carries out a high-speed plasma etching process on the substrate 1 in the high-speed etching vacuum chamber 10. Therein, in an embodiment of the present invention, the first radio frequency plasma module 11 is able to etch the substrate 1 in an etching speed between 0.2 μm/minute and 0.5 μm/minute, and the surface roughness Ra of the substrate 1 underwent the high-speed plasma etching process is between 0.5 μm to 2.0 μm. In a preferred embodiment, the high-speed etching vacuum chamber 10 comprises a first vacuuming module 12 to ensure the vacuum level in the high-speed etching vacuum chamber 10.

In another preferred embodiment, the high-speed etching vacuum chamber 10 further comprises a second radio frequency plasma module 13 disposed corresponding to the first radio frequency plasma module 11 (as shown by FIG. 2), with a plasma space S formed between the first radio frequency plasma module 11 and the second radio frequency plasma module 13, such that the substrate 1 undergoes the high-speed plasma etching process in the plasma space S.

In a preferred embodiment, the high-speed etching vacuum chamber 10 further comprises a fix module 14 disposed in the plasma space S for fixing the substrate 1. Also, the high-speed etching vacuum chamber 10 further comprises a movement module 15 connected with the second radio frequency plasma module 13. The movement module 15 controls the second radio frequency plasma module 13 to pass through the carrier board 40 to carry the substrate 1 to move toward the first radio frequency plasma module 11, such that the second radio frequency plasma module 13 and the fix module 14 fix the substrate 1. In the embodiment, the carrier board 40 is allowed to be a frame body. When the high-speed plasma etching process is finished, the movement module 15 controls the second radio frequency plasma module 13 to move away from the first radio frequency plasma module 11 so that the substrate 1 is placed on the carrier board 40 again. Therefore, the substrate 1 is prevented from warpage due to thermal factors in the plasma etching process, increasing the manufacturing yield of the substrate 1. In a preferred embodiment, the movement module 15 is allowed to perform the movement through, for example but not limited to, a motor, pneumatic cylinder, or hydraulic cylinder.

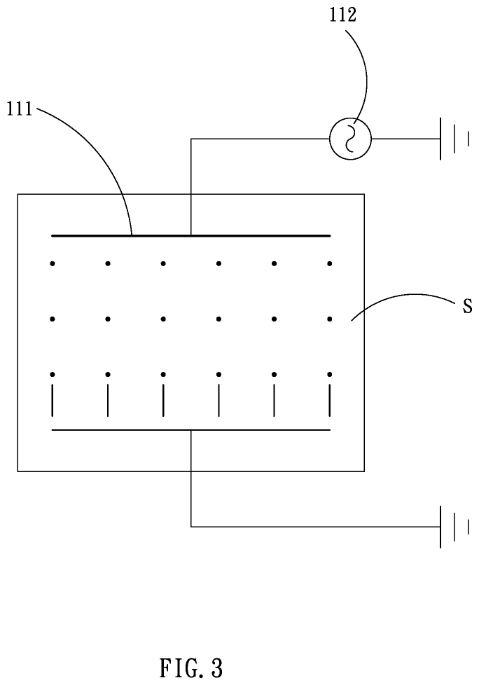

Referring to FIG. 3, a schematic view of the circuit of the first radio frequency plasma module 11 is shown. The first radio frequency plasma module 11 controls the density of plasma through a first electrode 111 and a first plasma source 112, so as to carry out the high-speed plasma etching process on the substrate 1 in the high-speed etching vacuum chamber 10, thereby efficiently obtaining the substrate 1 underwent the deep etching operation.

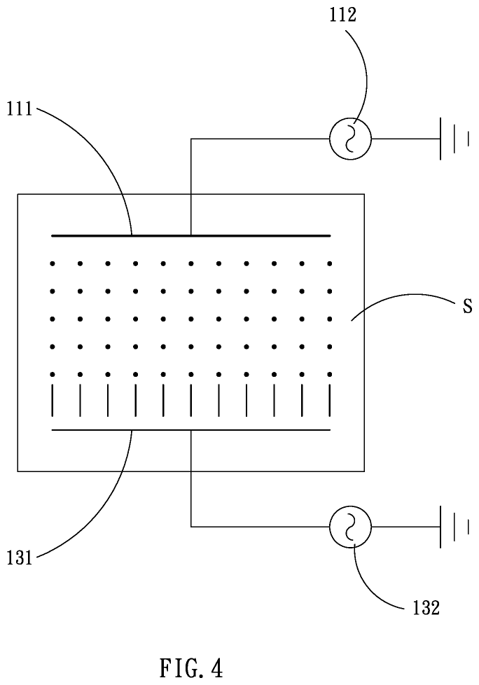

Referring to FIG. 4, the schematic view of the circuit of the first radio frequency plasma module 11 in accordance with another preferred embodiment is shown. The difference between FIG. 4 and FIG. 3 lies in that the high-speed etching vacuum chamber 10 comprises the second radio frequency plasma module 13, which has a second electrode 131 and a second plasma source 132. Therein, the first radio frequency plasma module 11 controls the density of the plasma, and the second radio frequency plasma module 13 controls the ion energy of the plasma, so that the plasma in the plasma space S is modified as shown by FIG. 4, thereby fulfilling different plasma etching requirements of the substrate 1. Further, the first radio frequency plasma module 11 and the second radio frequency plasma module 13 are allowed to apply any one of the reactive ion etching and inductively coupled plasma system, respectively.

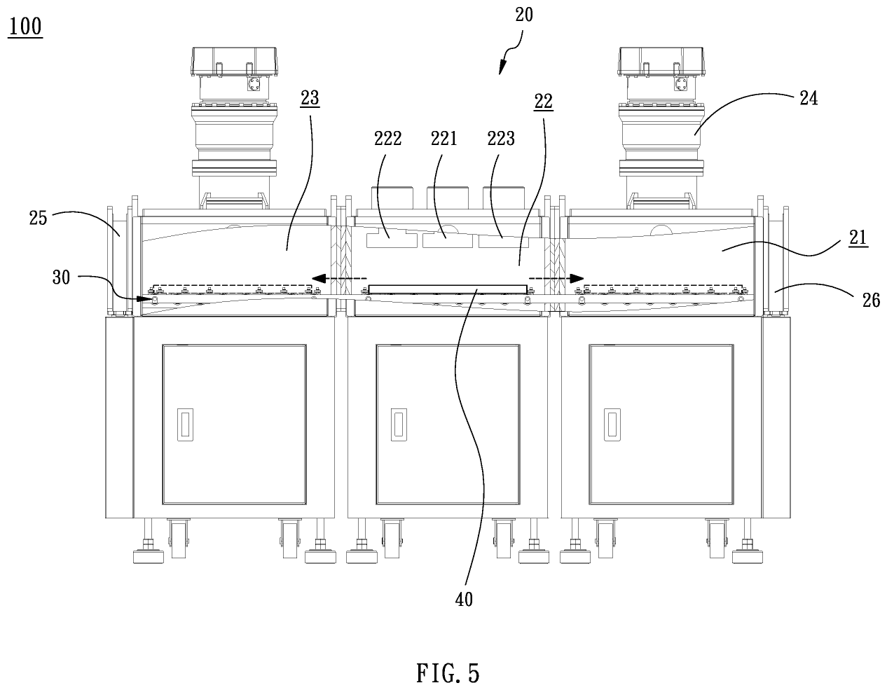

The low-speed etching vacuum chamber 20 is connected with the high-speed etching vacuum chamber 10, so as to receive the substrate 1 underwent the deep etching operation. Also, referring to FIG. 5, the low-speed etching vacuum chamber 20 comprises a first buffer area 21, a linear plasma area 22, and a second buffer area 23 that are orderly disposed and in communication with each other. The first buffer area 21 neighbors the high-speed etching vacuum chamber 10. The linear plasma area 22 comprises a first linear plasma module 221 therein for carrying out a low-speed plasma etching process on the substrate 1. Therein, the first linear plasma module 221 is allowed to be a DC linear electrode, such as a linear ion source, linear ion beam, linear ion gun, or other plasma modules processed with high density plasma (HDP). In an embodiment, the first linear plasma module 221 is able to etch the substrate 1 in an etching speed between 0.02 μm/minute and 0.1 μm/minute, and the surface roughness Ra of the substrate 1 underwent the low-speed plasma etching process is between 0.05 μm to 0.5 μm. And referring to FIG. 5, the conveyance device 30 enables the substrate 1 on the carrier board 40 to unidirectionally move or reciprocate between the first buffer area 21, the linear plasma area 22, and the second buffer area 23. The first linear plasma module 221 outputs the plasma with equal power from the top toward the bottom along a moving direction perpendicular to the substrate 1, so as to carry out an even and fine plasma etching process on the substrate 1. Therefore, the substrate 1 subsequently undergoes a sputter coating process acquires a lower resistance value, increasing the manufacturing yield of the substrate 1.

Furthermore, the linear plasma area 22 comprises a second linear plasma module 222 and a third linear plasma module 223, therein the first linear plasma module 221, the second linear plasma module 222, and the third linear plasma module 223 are orderly disposed in the low-speed etching vacuum chamber 20. Therefore, a plurality of linear plasma modules carry out the plasma etching process on the substrate 1 to improve the efficiency of the fine etching operation of the substrate 1. In a preferred embodiment, the low-speed etching vacuum chamber 20 comprises a second vacuuming module 24 for controlling the vacuum level in the low-speed etching vacuum chamber 20. Therein, two second vacuuming modules 24 are included (as shown by FIG. 5) and disposed in the first buffer area 21 and the second buffer area 23, respectively.

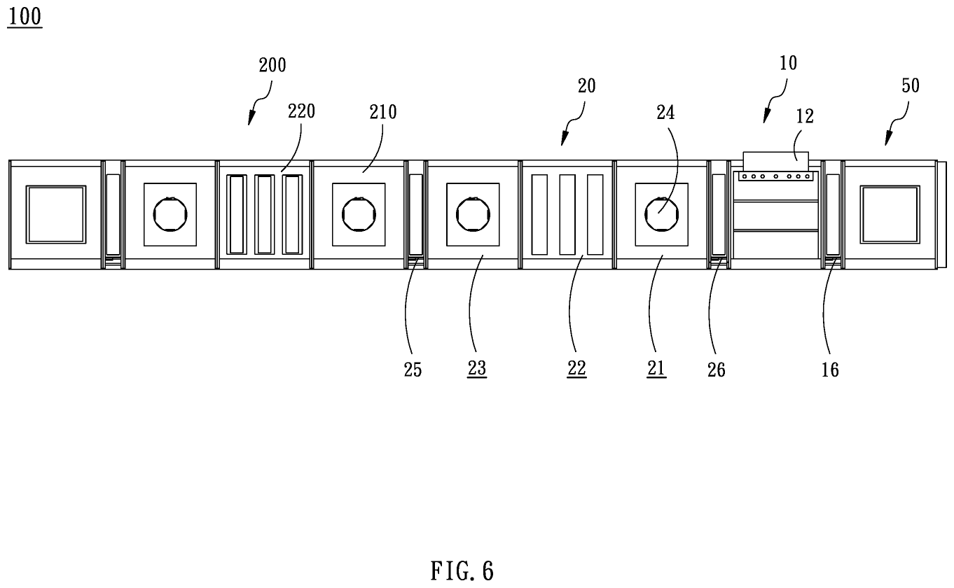

Referring to FIG. 6, in a preferred embodiment, the continuous processing mechanism 100 further comprises a loading station 50 disposed on one side of the high-speed etching vacuum chamber 10 away from the low-speed etching vacuum chamber 20 for inputting the substrate 1 to the high-speed etching vacuum chamber 10. In an embodiment, the high-speed etching vacuum chamber 10 is allowed to be connected with one or more chambers in series, including the loading station 50 or other pre-processing chambers; alternatively, the loading station 50 is used as a pre-processing chamber, and the pre-processing operations include, for example but not limited to, pre-cleaning, surface micro-etching processing, or low vacuum pre-processing of the substrate 1. Therein, the high-speed etching vacuum chamber 10 comprises a loading gate 16 neighboring the loading station 50. The low-speed etching vacuum chamber 20 comprises a first buffer gate 25 disposed on one side of the second buffer area 23 away from the loading station 50. The loading gate 16 controls the communication between the high-speed etching vacuum chamber 10 and the loading station 50, such that the substrate 1 is allowed to be inputted into the high-speed etching vacuum chamber 10 through the loading gate 16. The substrate 1 underwent the fine etching process is outputted from the low-speed etching vacuum chamber 20 through the first buffer gate 25. Through the opening and closing of the loading gate 16 and the first buffer gate 25, in cooperation with the vacuuming operation of the first vacuuming module 12 and the second vacuuming module 24, the internal space of the high-speed etching vacuum chamber 10 and the low-speed etching vacuum chamber 20 are isolated from the external space, such that the internal spaces of the two plasma etching chambers form a vacuum status. After loading the substrate 1, the loading station 50 is allowed to be vacuumed in a lower level to achieve an initial vacuum effect, so that when the loading gate 16 opens for the substrate 1 to be inputted into the high-speed etching vacuum chamber 10, there is no need to carry out the vacuuming process from the status of the atmosphere pressure, so as to reduce the time consumption. Besides, the high-speed etching vacuum chamber 10 and the low-speed etching vacuum chamber 20 comprise a corresponding inhaling module, respectively (not shown), so as to provide the specific gas needed for plasma generation. When the gas needed by the high-speed etching vacuum chamber 10 and the low-speed etching vacuum chamber 20 for the process are different, the second vacuuming module 24 disposed in the first buffer area 21 is able to facilitate a rapid air evacuation, preventing the interference of different gases for different processes. Also, by controlling the air evacuation speed of the first vacuuming module 12 and the second vacuuming module 24 and incorporating the inhaling module, the high-speed etching vacuum chamber 10 and the low-speed etching vacuum chamber 20 are allowed to have different vacuum levels.

Further, the low-speed etching vacuum chamber 20 comprises a second buffer gate 26 disposed on one side of the first buffer area 21 neighboring the high-speed etching vacuum chamber 10. The second buffer gate 26 controls the communication between the high-speed etching vacuum chamber 10 and the low-speed etching vacuum chamber 20, such that the internal spaces of the high-speed etching vacuum chamber 10 and the low-speed etching vacuum chamber 20 are in an independent vacuum status, respectively, so as to facilitate the respective plasma etching operations, thereby preventing the interference between the chambers. Therein, the pressure value in the high-speed etching vacuum chamber 10 is higher than the pressure value of the low-speed etching vacuum chamber 20. For example, the pressure value in the high-speed etching vacuum chamber 10 ranges from 5×10⁻⁵ torr to 1×10⁻¹ torr, and the pressure value in the low-speed etching vacuum chamber 20 ranges from 1×10⁻⁷ torr to 1×10⁻³ torr.

Referring to FIG. 6, the continuous processing mechanism 100 further comprises a processing equipment 200 disposed on one side of the low-speed etching vacuum chamber 20 away from the high-speed etching vacuum chamber 10. The processing equipment 200 receives the substrate 1 conveyed from the low-speed etching vacuum chamber 20. The processing equipment 200 comprises a buffer chamber 210 and a sputter coating chamber 220. In this embodiment, the sputter coating chamber 220 is arranged between two buffer chambers 210 (as shown by FIG. 6.), so as to carry out the sputter coating process on the substrate 1 according to different operation demands. For example, the surface of the substrate 1 is able to be sputter coated with metal material, such as copper, tin, and titanium to obtain properties of anti-corrosion, anti-oxidation, or heat resistance.

In a preferred embodiment, a plurality of substrates 1 are included, comprising at least a first substrate and a second substrate. Referring to FIG. 6, when the first substrate is undergoing the low-speed plasma etching process in the low-speed etching vacuum chamber 20, the second substrate is allowed to be simultaneously undergoing the high-speed plasma etching process in the high-speed etching vacuum chamber 10. Therefore, the continuous processing mechanism 100 is able to carry out the plasma etching processes of a plurality of substrates 1 in different chambers, so as to improve the overall efficiency. Then, when the low-speed plasma etching process of the first substrate is finished, the first substrate subsequently enters the processing equipment 200 to undergo the coating process. Also, when the high-speed plasma etching process of the second substrate is finished, the second substrate then enters the low-speed etching vacuum chamber 20 for the subsequent low-speed plasma etching process. Next, a third substate is able to simultaneously enter the high-speed etching vacuum chamber 10 for the high-speed plasma etching process.

With the foregoing configuration, technical features of the present invention will be illustrated below.

The present invention carries out the high-speed etching process of the substrate 1 through the first radio frequency plasma module 11, so as to efficiently obtain the substrate 1 underwent the deep etching operation. Next, the substrate 1 finished the deep etching operation is inputted into the low-speed etching vacuum chamber 20 for the first linear plasma module 221 to carry out the even and fine etching process on the substrate 1, so as to obtain the substrate 1 underwent the fine etching operation. Therefore, besides efficiently obtaining the deep etched substrate 1, the present invention is also able to achieve a high surface fineness of the substrate 1. Further, if the substrate 1 is to undergo a subsequent sputter coating process, the sputter coated substrate 1 acquires a lower resistance value (such as smaller than 20 milliohms), increasing the manufacturing yield of the substrate 1.

The present invention is able to complete efficient etching and precise fine etching at one time without the need for separate plasma equipment and development and etching equipment to perform respective processes, so as to resolve the issue of conveying the substrate 1 between different equipment, which requires time-consuming vacuum breaking and re-vacuuming operation. Therefore, the present invention effectively improves the production efficiency of the overall semiconductor manufacturing process.

When the first substrate is undergoing the fine plasma etching process in the low-speed etching vacuum chamber 20, the second substrate is allowed to be simultaneously undergoing the high-speed plasma etching process in the high-speed etching vacuum chamber 10, such that the continuous processing mechanism 100 carries out the plasma etching processes of a plurality of substrates 1 in different chambers, simultaneously, thereby increasing the overall efficiency.

The first linear plasma module 221 is a DC linear electrode. Said DC linear electrode is capable of evenly and finely etching the substrate 1, preventing the roughness difference of the surface of the substrate 1.

According to different operation conditions of the present invention, the first radio frequency plasma module 11 controls the density of the plasma, and the second radio frequency plasma module 13 controls the ion energy of the plasma, flexibly fulfilling different plasma etching requirements for the substrate 1.

The present invention fixes the substrate 1 through the fix module 14 disposed in the plasma space S, preventing the warpage of the substrate 1 during the plasma process due to thermal factors, thereby increasing the manufacturing yield of the substrate 1.

With the substrate 1 reciprocating between the first buffer area 21, the linear plasma area 22, and the second buffer area 23, the substrate 1 is allowed to completely pass through the first linear plasma module 221, achieving an even etching effect of the substrate 1 surface.

The present invention carries out the plasma etching on the substrate 1 by using the first linear plasma module 221, the second linear plasma module 222, and the third linear plasma module 223 that are disposed in a continuous arrangement, further improving efficiency of the fine etching process of the substrate 1.

The second buffer gate 26 of the present application controls the communication between the high-speed etching vacuum chamber 10 and the low-speed etching vacuum chamber 20, such that the high-speed etching vacuum chamber 10 and the low-speed etching vacuum chamber 20 are in an independent vacuum status, respectively, so as to facilitate the respective plasma etching operations, thereby preventing the interference between the chambers.

The processing equipment 200 of the present invention receives the substrate 1 conveyed from the low-speed etching vacuum chamber 20, and is capable of directly and efficiently sputter coating the substrate 1 to increase the processing efficiency and improve the overall production efficiency.

The aforementioned objectives do not prevent the existence of other objectives. Those objectives derivable from the specification, claims, or drawings of the present invention by a person having ordinary skill in the field of the invention are also included in the scope of objectives of the present invention. Therefore, the objectives of the present invention are not limited to the aforementioned objectives.

Although particular embodiments of the invention have been described in detail for purposes of illustration, various modifications and enhancements may be made without departing from the spirit and scope of the invention. Accordingly, the invention is not to be limited except as by the appended claims. cm What is claimed is:

1. A continuous processing mechanism for dual effect plasma etching for carrying out a plasma etching process on at least a substrate, the continuous processing mechanism comprising:
a first high-speed etching vacuum chamber comprising a first radio frequency plasma module for carrying out a high-speed plasma etching process on the substrate; and
a low-speed etching vacuum chamber connected with the high-speed etching vacuum chamber, and comprising a first buffer area, a linear plasma area, and a second buffer area that are orderly disposed and in communication with each other, the first buffer area neighboring the high-speed etching vacuum chamber, the linear plasma area comprising a first linear plasma module therein for carrying out a low-speed plasma etching process on the at least one substrate, the at least one substrate unidirectionally moving or reciprocating between the first buffer area, the linear plasma area, and the second buffer area, so as to carry out the low-speed plasma etching process on the at least one substrate.

2. The continuous processing mechanism of claim 1, further comprising a loading station disposed on one side of the high-speed etching vacuum chamber away from the low-speed etching vacuum chamber, the loading station being configured to input the at least one substrate to the high-speed etching vacuum chamber.

3. The continuous processing mechanism of claim 2, wherein the high-speed etching vacuum chamber comprises a loading gate neighboring the loading station; the low-speed etching vacuum chamber comprises a first buffer gate disposed on one side of the second buffer area away from the loading station.

4. The continuous processing mechanism of claim 3, wherein the low-speed etching vacuum chamber comprises a second buffer gate disposed on one side of the first buffer area neighboring the high-speed etching vacuum chamber; the second buffer gate is configured to control a communication between the high-speed etching vacuum chamber and the low-speed etching vacuum chamber.

5. The continuous processing mechanism of claim 4, wherein a pressure value in the high-speed etching vacuum chamber ranges from 5×10⁻⁵ torr to 1×10⁻¹ torr, and a pressure value in the low-speed etching vacuum chamber ranges from 1×10⁻⁷ torr to 1×10⁻³ torr, and the pressure value in the high-speed etching vacuum chamber is higher than that in the low-speed etching vacuum chamber.

6. The continuous processing mechanism of claim 1, further comprising a processing equipment disposed on one side of the low-speed etching vacuum chamber away from the high-speed etching vacuum chamber, and configured to carry out a sputter coating process on the substrate.

7. The continuous processing mechanism of claim 1, wherein the high-speed etching vacuum chamber comprises a second radio frequency plasma module corresponding to the first radio frequency plasma module; a plasma space is formed between the first radio frequency plasma module and the second radio frequency plasma module, and the at least one substrate undergoes the high-speed plasma etching process in the plasma space.

8. The continuous processing mechanism of claim 7, wherein the first radio frequency plasma module and the second radio frequency plasma module apply one of reactive ion etching and inductively coupled plasma system, respectively.

9. The continuous processing mechanism of claim 7, wherein the high-speed etching vacuum chamber further comprises a fix module disposed in the plasma space and configured to fix the substrate.

10. The continuous processing mechanism of claim 9, wherein the high-speed etching vacuum chamber comprises a movement module connected with the second radio frequency plasma module; the movement module is configured to control the second radio frequency plasma module to carry the at least one substrate to move toward the first radio frequency plasma module, such that the second radio frequency plasma module and the fix module fix the at least one substrate.

11. The continuous processing mechanism of claim 1, wherein a second linear plasma module and a third linear plasma module are disposed in the linear plasma area; the first linear plasma module, the second linear plasma module, and the third linear plasma module are orderly disposed in the low-speed etching vacuum chamber.

12. The continuous processing mechanism of claim 1, further comprising a carrier board for holding the at least one substrate.

13. The continuous processing mechanism of claim 1, wherein the high-speed etching vacuum chamber comprises a first vacuuming module configured to carry out a vacuuming process in the high-speed etching vacuum chamber.

14. The continuous processing mechanism of claim 1, wherein the low-speed etching vacuum chamber comprises a second vacuuming module configured to carry out a vacuuming process in the low-speed etching vacuum chamber.

15. The continuous processing mechanism of claim 14, wherein two second vacuuming modules are included and disposed in the first buffer area and the second buffer area, respectively.

16. The continuous processing mechanism of claim 1, wherein a plurality of the substrates are included, comprising at least a first substrate and a second substrate; when the first substrate undergoes the low-speed plasma etching process in the low-speed etching vacuum chamber, the second substrate undergoes the high-speed plasma etching process in the high-speed etching vacuum chamber.
